(19) United States
(12) Patent Application Publication
(10) Pub. No.: US 2026/0312602 A1
(43) Pub. Date: Oct. 8, 2026

(54) TECHNIQUE FOR GENERATING A NEW OUTPUT VALUE FOR INCLUSION WITHIN A SEQUENCE OF OUTPUT VALUES THAT ARE OUTPUT IN A GIVEN REPRESENTATION

(71) Applicant: Arm Limited, Cambridge (GB)

(72) Inventor: Simon John CRASKE, Cambridge (GB)

(73) Assignee: Arm Limited, Cambridge (GB)

(21) Appl. No.: 19/483,411

(22) PCT Filed: Feb. 6, 2024
(86) PCT No.: PCT/GB2024/050315

§ 371 Date: Nov. 11, 2025

(30) Foreign Application Priority Data
May 16, 2023 (GB) 2307282.0

(51) Int. Cl. H03M 7/16

(52) U.S. Cl. CPC H03M 7/16

(57) ABSTRACT

An apparatus and method are provided for producing a new output value for inclusion within a sequence of output values that are output in a given representation. An input interface receives a target value, and modification circuitry determines a new output value in the sequence from a current output value in the sequence in dependence on the target value, such that the new output value meets a determined condition. The determined condition requires both that the new output value has a Hamming distance of 1 relative to the current output value when the new output value and the current output value are expressed in the given representation, and that the new output value lies between the current output value and the target value. The modification circuitry is arranged, when there are at least two possible new output values that meet the determined condition, to select as the new output value the possible new output value that is closest to the target value from amongst the at least two possible new output values.

### BACKGROUND

The present technique relates to the generation of a sequence of output values that are output in a given representation, and in particular to the generation of a new output value for inclusion within the sequence, in dependence on a received target value.

Such a technique can be used in a variety of situations, for example when generating a sequence of output values that seek to follow changes in a corresponding sequence of received target values. By appropriate choice of the given representation, this can ensure a more reliable detection of the changes in the output values in the sequence by recipient devices than would be the case were those recipient devices instead configured to directly receive the corresponding sequence of target values and to seek to detect the changes in the target values. For example, the given representation can be chosen such that, when a default change in value occurs between a given output value and a next output value in the sequence, the given output value and the next output value will have a Hamming distance of 1 when expressed in the given representation. This can facilitate reliable detection by a recipient device of the transition from the given output value to the next output value, even if the recipient device is operating asynchronously to the device transmitting the output values.

However, it is possible that successive target values in the sequence may change by differing amounts, and in particular will not always change by the default change amount (e.g. the minimal adjustment amount). For example, the amount by which consecutive values of the target value change may be dependent on the clock frequency at which the circuitry generating the target values is operating, and that clock frequency may itself be varied over time. It would hence be desirable to be able to accommodate arbitrary changes in the target values, while still producing a corresponding sequence of output values that seek to follow the changes in the corresponding sequence of received target values, and while still ensuring that the sequence of output values can be reliably detected.

### SUMMARY

In a first example arrangement, there is provided an apparatus comprising: output circuitry arranged to output a sequence of output values in a given representation; an input interface to receive a target value; and modification circuitry to determine a new output value in the sequence from a current output value in the sequence in dependence on the target value, such that the new output value meets a determined condition, where the determined condition requires both that the new output value has a Hamming distance of 1 relative to the current output value when the new output value and the current output value are expressed in the given representation, and that the new output value lies between the current output value and the target value; wherein the modification circuitry is arranged, when there are at least two possible new output values that meet the determined condition, to select as the new output value the possible new output value that is closest to the target value from amongst the at least two possible new output values.

In another example arrangement, there is provided a method of producing a new output value for inclusion within a sequence of output values that are output in a given representation, comprising: receiving a target value; employing modification circuitry to determine the new output value in the sequence from a current output value in the sequence in dependence on the target value, such that the new output value meets a determined condition, where the determined condition requires both that the new output value has a Hamming distance of 1 relative to the current output value when the new output value and the current output value are expressed in the given representation, and that the new output value lies between the current output value and the target value; and when there are at least two possible new output values that meet the determined condition, selecting as the new output value the possible new output value that is closest to the target value from amongst the at least two possible new output values.

In a still further example arrangement, there is provided a computer-readable medium to store computer-readable code for fabrication of an apparatus comprising: output circuitry arranged to output a sequence of output values in a given representation; an input interface to receive a target value; and modification circuitry to determine a new output value in the sequence from a current output value in the sequence in dependence on the target value, such that the new output value meets a determined condition, where the determined condition requires both that the new output value has a Hamming distance of 1 relative to the current output value when the new output value and the current output value are expressed in the given representation, and that the new output value lies between the current output value and the target value; wherein the modification circuitry is arranged, when there are at least two possible new output values that meet the determined condition, to select as the new output value the possible new output value that is closest to the target value from amongst the at least two possible new output values. Such computer-readable code can be disposed in any known transitory computer-readable medium (such as wired or wireless transmission of code over a network) or non-transitory computer-readable medium such as semiconductor, magnetic disk, or optical disc.

In a yet further example arrangement there is provided a system comprising: the apparatus according to the above-mentioned first example arrangement, implemented in at least one packaged chip; at least one system component; and a board, wherein the at least one packaged chip and the at least one system component are assembled on the board.

In a still further example arrangement there is provided a chip-containing product comprising the above-mentioned system assembled on a further board with at least one other product component.

### BRIEF DESCRIPTION OF THE DRAWINGS

The present technique will be described further, by way of illustration only, with reference to examples thereof as illustrated in the accompanying drawings, in which:

FIG. 1 is a block diagram of an apparatus in accordance with one example implementation;

FIG. 2 is a flow diagram illustrating steps performed by the apparatus of FIG. 1, in accordance with one example implementation;

FIGS. 3A and 3B provide a flow diagram illustrating in more detail steps that may be performed by an apparatus in accordance with one example implementation;

FIGS. 4 to 6 schematically illustrate particular examples of how a new output value may be generated from a current output value in dependence on a target value, in accordance with one example implementation;

FIG. 7 schematically illustrates a system in which the apparatus described herein may be employed, in accordance with one example implementation; and

FIG. 8 illustrates an example of a system and chip-containing product.

### DESCRIPTION OF EXAMPLES

In one example implementation, an apparatus is provided that has output circuitry that is used to output a sequence of output values in a given representation. An input interface is arranged to receive a target value, and modification circuitry is arranged to determine a new output value in the sequence from a current output value in the sequence in dependence on the target value. When determining the new output value, the modification circuitry is arranged to ensure that the new output value meets a determined condition, that condition requiring both that the new output value has a Hamming distance of 1 relative to the current output value when the new output value and the current output value are expressed in the given representation, and that the new output value lies between the current output value and the target value. The requirement for a Hamming distance of 1 ensures that there is only a single digit change between adjacent output values in the sequence in the given representation, which removes the need for any synchronisation circuitry and allows a recipient device to reliably detect the transition of the change in the output value from the current output value to the new output value. Further the requirement for the new output value to lie between the current output value and the target value means enables the new output value to move closer to the target value than the current output value (hence seeking to follow the target value), but without overshooting the target value.

Furthermore, the modification circuitry is arranged, when there are at least two possible new output values that meet the determined condition, to select as the new output value the possible new output value that is closest to the target value from amongst the at least two possible new output values.

The above technique exploits the fact that, whilst the given representation may always produce a Hamming distance of 1 between two output values that differ by a default amount (e.g. the minimum adjustment amount), there may in some instances be larger adjustments in successive output values that will also result in those successive output values having a Hamming distance of 1 when in the given representation, and which may also meet the requirement of generating a new output value that lies between the current output value and the target value. By seeking to detect such situations, it is possible to produce an apparatus that can accommodate arbitrary changes in a sequence of target values, whilst producing a corresponding sequence of output values that can accurately follow the sequence of target values by adjusting responsively to varying amounts of change in the target values, and whilst all the time ensuring that successive output values in the sequence in the given representation have a Hamming distance of 1 with respect to each other.

The target value received at the input interface can take a variety of forms. However, by way of example, in one particular implementation the target value may take the form of a global time value. The amount by which successive instances of the target value received at the input interface change may vary over time, for example due to changes in the clock frequency at which the entity generating the global time value is operating, and/or changes in the clock frequency at which the apparatus is sampling the global time value, and hence there may be arbitrary changes in the target value, where some changes are larger than other changes. The technique described above can adjust to these arbitrary changes, by seeking to determine new output values that allow the sequence of output values to more rapidly reflect changes in the corresponding sequence of target values, and hence more accurately follow the target values, whilst all the time ensuring that successive output values in the sequence have a Hamming distance of 1 when expressed in the given representation. Further, the described technique ensures that any new output value chosen will not overshoot the corresponding target value. In the context of a global time value propagation, this ensures that no recipient device ever receives an output value that indicates a global time value exceeding the originally generated global time value provided as the target value.

In the above example of a global time value, it will be expected each successive instance of the target value identifies an increased value relative to the previously observed target value, and hence the sequence of target values received may be monotonic, arbitrarily increasing, values. However, the technique can also be used in association with a series of target values that are monotonic, but arbitrarily decreasing, values. Furthermore, in one example implementation the apparatus can accommodate a sequence of target values that can both increase or decrease by arbitrary amounts between successive target values in the sequence.

The given representation may vary dependent on implementation, but in one example implementation is a Gray code representation. This provides a particularly efficient representation to use, as the Gray code representation is well-defined, and it is straightforward to transition between the Gray code representation and the equivalent binary representation of any given value. This can hence simplify the functionality of the modification circuitry when seeking to determine potential output values that meet the earlier-mentioned determined condition.

There are a number of ways in which the modification circuitry can be arranged to indicate the new output value. However, in one example implementation the output circuitry has a storage to store the current output value in the given representation, and the modification circuitry is arranged to output a modification value identifying which bit of the current output value in the given representation requires its bit value to be flipped in order to generate the new output value in the given representation. The output circuitry can then be arranged to use the modification value to update the storage to identify the new output value in the given representation.

The modification value can take a variety of forms. For example, it may take the form of a binary value with enough bits to enable any one of the individual bits making up the output value in the given representation to be identified. Purely by way of specific example, if the output value in the given representation comprises a 32-bit value, a 5-bit binary value could be used as the modification value to identify which individual bit within the current output value in the given representation needs to have its bit value flipped in order to transition from the current output value to the new output value in the given representation. In an alternative implementation, the modification value could be expressed as a one hot encoded value having the same number of bits as the number of bits within the output value in the given representation, and with a single bit in the one hot encoded value set to identify the bit position within the output value whose bit value should be flipped.

In one example implementation, at least each time a new instance of the target value is received at the input interface, the modification circuitry is arranged to determine the current output value from the output value in the given representation as currently stored in the storage, and to determine the new output value in the sequence from the determined current output value in dependence on the new instance of the target value. Whilst the modification circuitry may be arranged to perform a determination of the new output value each time the target value changes, in one example implementation it may also be arranged to continue re-determining a new output value whenever it is assessed that the current output value does not yet match the target value, and hence irrespective of whether the target value has been updated. For example, it could be arranged to perform such re-determination on each clock cycle of the apparatus, either due to the target value as sampled having changed from the previous target value, or due to the current output value as stored by the output circuitry not yet matching the target value.

The modification circuitry can take a variety of forms. In one example implementation, the modification circuitry comprises analysis circuitry to perform an analysis operation using both the target value in binary representation and the current output value in binary representation in order to determine one or more candidate bit positions whose bit value within the current output value in the given representation could be flipped in order to generate the new output value in the given representation. The modification circuitry further comprises evaluation circuitry arranged, when at least two candidate bit positions are determined, to evaluate which one of the candidate bit positions, were its bit value within the current output value in the given representation flipped in order to generate the new output value in the given representation, would result in the new output value that is closest to the target value whilst also lying between the current output value and the target value. Such an arrangement can provide a particularly simple and cost-effective arrangement for implementing the modification circuitry, providing a low-area solution. In an alternative implementation, such functionality of the modification circuitry could be implemented by software running on general purpose processing circuitry, if desired.

As mentioned earlier, in some example implementations the output value is maintained in the given representation, and when the modification circuitry is implemented in the manner discussed above then in one example implementation conversion circuitry may be provided to convert the current output value in the given representation into the current output value in binary representation, for provision to the modification circuitry.

There are a number of ways in which the analysis circuitry can be arranged to perform the earlier-mentioned analysis operation in order to determine one or more candidate bit positions. However, in one example implementation, the analysis circuitry is arranged to detect, as a first candidate bit position X, a most significant bit position at which a bit value in the target value in binary representation differs from a bit value in the current output value in binary representation. Such a determination of a first candidate bit position can be readily determined using both the target value and the current output value in binary representation. For example, an XOR operation can be performed using both the target value and the current output value in binary representation as inputs, with the most significant bit position in the output that has a logic 1 value indicating the first candidate bit position X. The output from the XOR operation can be converted into a thermometer encoding (where all bit positions from bit position X to bit position 0 are set to a logic 1 value) if desired.

Furthermore, the analysis circuitry may be arranged to detect, as a second candidate bit position Y, a next most significant bit position below the first candidate bit position X at which a bit value in the current output value in binary representation is a predetermined bit value, provided there is at least one bit position below the first candidate bit position X at which a bit value in the current output value in binary representation has the predetermined bit value. In one example implementation, a one-bit right shifted version of the earlier-mentioned thermometer encoding may be used, in combination with the current output value in binary representation, to determine this second candidate bit position Y.

In one example implementation, the evaluation circuitry can then be arranged to generate a candidate new output value that would be formed were the bit value at the first candidate bit position X within the current output value in the given representation flipped in order to generate the new output value in the given representation. If the evaluation circuitry then determines that the candidate new output value lies between the current output value and the target value, it can then be arranged to identify the first candidate bit position X as the bit position whose bit value within the current output value in the given representation is to be flipped in order to generate the new output value in the given representation. In one example implementation, the above-mentioned candidate new output value can be readily generated from the existing output value. For instance, in an example implementation where a Gray code is used as the given representation, the earlier-mentioned thermometer encoding and the current output value can be subjected to an XOR operation whose output then represents the candidate new output value.

In one example implementation, when it is determined that the above-mentioned candidate new output value does not lie between the current output value and the target value, the evaluation circuitry may be arranged to identify the second candidate bit position Y as the bit position whose bit value within the current output value in the given representation is to be flipped in order to generate the new output value in the given representation. It has been found that in situations where the above-mentioned candidate new output value does not lie between the current output value and the target value (i.e. is not within an acceptable range of values), there will always be a bit position Y detected by the analysis circuitry, and accordingly that bit position can be used to indicate the bit value to be flipped in order to transition the current output value to the new output value in the given representation.

As mentioned earlier, in one example implementation the given representation is a Gray code representation. In such an implementation, the evaluation circuitry may be arranged to compute the candidate new output value in binary representation (C_{new}) from the current output value in binary representation (C) as:

$${C}_{n e w} = \{ C [ N - 1 : X + 1 ] , ∼ C [ X ; 0 ] \}$$

such that bits X to 0 in C_{new} are the inverse of the corresponding bits X to 0 in C. The evaluation circuitry may then be arranged to determine that the candidate new output value lies between the current output value and the target value when C_{new} is less than or equal to the target value in binary representation (for implementations where successive target values are increasing), or when C_{new} is greater than or equal to the target value in binary representation (for implementations where successive target values are decreasing).

As mentioned earlier, in one example implementation the analysis circuitry is arranged to determine, as the second candidate bit position Y, a next most significant bit position below the first candidate bit position X at which a bit value in the current output value in binary representation is a predetermined bit value, provided there is at least one bit position below the first candidate bit position X at which a bit value in the current output value in binary representation has the predetermined bit value. The predetermined bit value will depend upon whether the target values received at the input interface are increasing or decreasing. In one example implementation, the predetermined bit value is a logic 0 value when successive values of the target value as received at the input interface monotonically increase, whilst in contrast the predetermined bit value is a logic 1 value when successive values of the target value as received at the input interface monotonically decrease.

Whilst in some example implementations the apparatus will be used in situations where successive target values either only monotonically increase, or only monotonically decrease, the technique described herein can also be used in other situations. For example, when any given target value as received at the input interface is allowed to increase or decrease relative to a preceding target value as received at the input interface, the modification circuitry may be arranged to additionally comprise direction detection circuitry to determine whether a currently received target value is greater than or less than the current output value. The predetermined bit value is then set to a logic 0 value when the currently received target value is greater than the current output value, but is instead set to a logic 1 value when the currently received target value is less than the current output value.

Particular example implementations will now be discussed with reference to the accompanying figures.

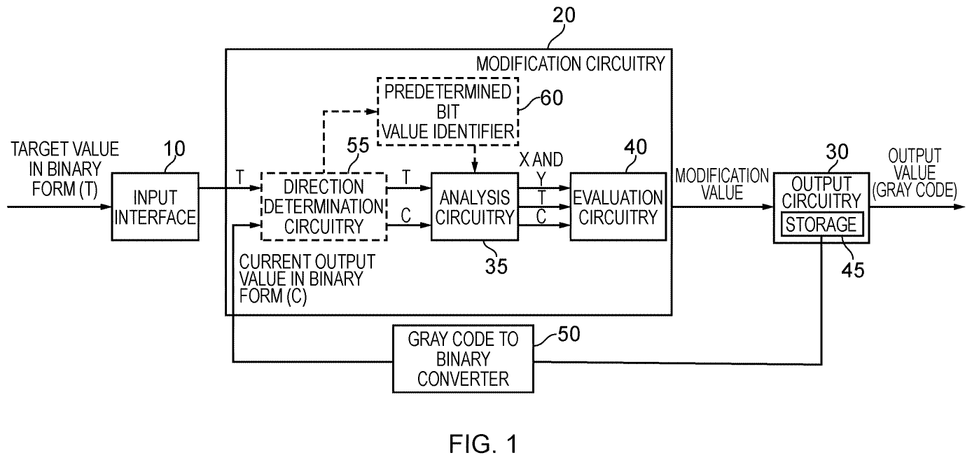

FIG. 1 is a block diagram of an apparatus in accordance with one example implementation. A sequence of target values is received at an input interface 10, and the apparatus is used to produce a sequence of output values from the output circuitry 30 that seeks to follow the sequence of target values. The output values are output in accordance with a given representation that is selected so as to seek to improve reliable detection of the changes in the output values. In one particular example implementation the given representation is a Gray code representation. A Gray code representation ensures that when an adjustment by a minimum adjustment value is made to a first value in order to produce a second value, the first value and the second value when expressed in Gray code representation will only differ by the value of a single bit (i.e. one bit within the first value in Gray code representation will have its bit value flipped in order to create the second value in Gray code representation). Hence, by using a Gray code representation, transitions in output values can more reliably be detected, even if the components receiving those output values are operating asynchronously to the apparatus producing them.

When two values differ only by the value of a single bit, those two values are said to have a Hamming distance of 1. However, in many practical situations adjacent target values within a sequence of target values received at the input interface will not necessarily differ from each other by only the minimum possible adjustment amount, and hence if each target value were merely converted directly into the equivalent Gray code representation it may not be the case that two adjacent output values in Gray code representation would have a Hamming distance of 1. The aim of the technique described herein is to ensure that adjacent output values produced by the apparatus do have a Hamming distance of 1, whilst still enabling the sequence of output values to seek to accurately follow the sequence of target values by adjusting responsively to varying amounts of change in the target values.

As shown in FIG. 1, the apparatus includes modification circuitry that receives each target value as received at the input interface 10. The target values may be received in a variety of forms, but in one example implementation are received in binary form. If received in a different form, the input interface may in one example implementation convert the target value into a binary form before forwarding the received target value to the modification circuitry. The target value in binary form is referred to in FIG. 1 as the target value T.

The output circuitry 30 is arranged to store within storage 45 a Gray code representation of the current output value. Upon a reset condition, the current output value in the storage will be reset to a defined value, for example all zeros. The current output value in Gray code form is provided to the modification circuitry 20 via the Gray code to binary converter circuit 50, such that the modification circuitry 20 receives the current output value in binary form, this current output value in binary form being referred to as the current output value C in FIG. 1.

The target value T and the current output value C are provided to analysis circuitry 35, optionally via direction determination circuitry 55 which will be described in more detail later. The analysis circuitry 35 is arranged to perform an analysis operation in order to determine one or more candidate bit positions whose bit value within the current output value in Gray code representation could be flipped in order to generate the new output value (i.e. the next output value in the sequence) in Gray code representation.

In particular, in one example implementation, the analysis circuitry is arranged to detect, as a first candidate bit position X, a most significant bit position at which a bit value in the target value in binary representation T differs from a bit value in the current output value in binary representation C. In one example implementation, this is achieved by performing an XOR operation on the provided binary values T and C to produce a result value, with the most significant bit position in the result value that has a logic 1 value indicating the first candidate bit position X. The result value from the XOR operation can be converted into a thermometer encoding (where all bit positions from bit position X to bit position 0 are set to a logic 1 value) if desired.

In addition, the analysis circuitry is arranged to detect, as a second candidate bit position Y, the next most significant bit position below the first candidate bit position X at which a bit value in the current output value in binary representation C is a predetermined bit value, provided there is at least one bit position below the first candidate bit position X at which a bit value in the current output value in binary representation C has the predetermined bit value. The predetermined bit value will be dependent on whether the target values in the sequence are increasing or decreasing. If the target values are monotonically increasing then the predetermined bit value will be a logic 0 value, whereas if the target values are monotonically decreasing then the predetermined bit value will be a logic 1 value. In one example implementation the target values will be constrained to be monotonically increasing values, or in an alternative example implementation will be constrained to be monotonically decreasing values. However, the techniques described herein can also be used if the target values are not constrained in that way. In particular, in implementations where the target values may either increase or decrease, direction determination circuitry 55 can be used to determine whether the newly received target value is larger than or smaller than the current output value, and to trigger predetermined bit value identifier circuitry 60 to identify the appropriate predetermined bit value accordingly (i.e. a logic 0 value if the target value is larger than the current output value, or a logic 1 value if the target value is smaller than the current output value).

There are a number of ways in which the analysis circuitry 35 can be arranged to detect the second candidate bit position Y, but in one example implementation a one-bit right shifted version of the earlier-mentioned thermometer encoding may be used, in combination with the current output value in binary representation C, to determine the second candidate bit position Y. For example, assuming the predetermined bit value is a logic 0 value, this can be achieved by inverting each bit of the current output value and subjecting that inverted bit to an AND operation with the corresponding bit from the right shifted version of the thermometer encoding, and detecting the most significant bit of the result that has a logic 1 value as being bit position Y.

As shown in FIG. 1, the binary values T and C are provided from the analysis circuitry 35 to evaluation circuitry 40, along with the first and second candidate bit positions X and Y. The evaluation circuitry is then arranged to generate a candidate new output value that would be formed were the bit value at the first candidate bit position X within the current output value in Gray code representation flipped in order to generate the new output value in Gray code representation. The evaluation circuitry 40 then determines whether the candidate new output value lies between the current output value and the target value, and if so is arranged to identify the first candidate bit position X as the bit position whose bit value within the current output value in the Gray code representation is to be flipped in order to generate the new output value in Gray code representation. Otherwise, the second candidate bit position Y is indicated as the bit position whose bit value within the current output value in Gray code representation is to be flipped in order to generate the new output value in Gray code representation. There are a number of ways in which the evaluation circuitry can generate the candidate new output value, but in one example implementation the earlier-mentioned thermometer encoding and the current output value C are subjected to an XOR operation to generate the new candidate new output value.

The bit position determined by the evaluation circuitry is then provided as a modification value to the output circuitry 30 in order to cause the output value in Gray code form as stored within the storage 45 to be updated. The modification value can take a variety of forms, but in one example implementation is provided as a one hot encoding value who set bit identifies the bit position in the current output value in Gray code representation whose bit value is to be flipped in order to generate the new output value in Gray code representation.

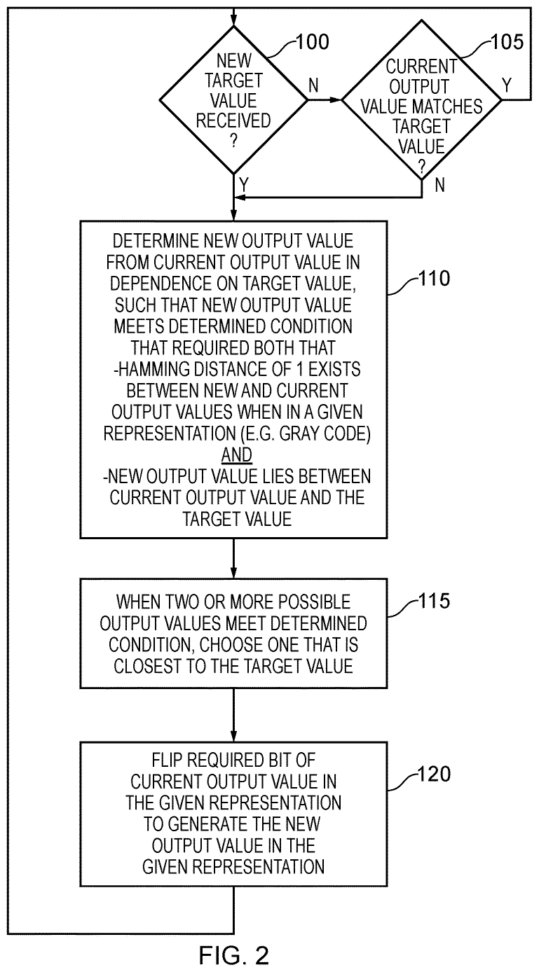

FIG. 2 is a flow diagram illustrating the operation of the apparatus of FIG. 1 in accordance with one example implementation. At step 100, it is determined whether a new target value has been received, and if not it is determined at step 105 whether the current output value matches the target value. If either a new target value is received, or the current output value does not match the most recently provided target value, then the process proceeds to step 110. It should be noted that in one example implementation the target value as presented to the input interface 10 is sampled by the apparatus during every clock cycle, and hence at each clock cycle there can be considered to be a new target value received, irrespective of whether the currently sampled target value actually differs from the previously sampled target value, and in such an implementation the evaluation of step 105 is not needed, and it may merely be assumed at step 100 that a new target value has been received.

At step 110, the modification circuitry is arranged to determine a new output value from the current output value, in dependence on the provided target value, and in particular is arranged to constrain the new output value so that it meets a determined condition. The determined condition requires firstly that a Hamming distance of 1 exists between the new output value and the current output value when both values are expressed in Gray code representation (or more generally when both values are expressed in the given representation used by the apparatus, of which a Gray code representation is one example implementation). However, in addition it is a requirement of the determined condition that the new output value lies between the current output value and the target value, so that the output value cannot be adjusted beyond the target value, i.e. will not overshoot the corresponding target value.

As indicated at step 115, when two or more possible output values meet the determined condition, then the modification circuitry 20 is arranged to select the one of those possible output values that is closest to the target value, thereby allowing changes in the output values to more quickly adjust to changes in the target values provided to the apparatus. The modification circuitry then produces a modification value to identify the bit position in the current output value in Gray code representation whose bit value should be flipped in order to generate the new output value in Gray code representation, and at step 120 the output circuitry flips that required bit in order to generate the new output value in Gray code representation and the process then returns to step 100 (as mentioned earlier, in other implementations a representation other than Gray code representation may be used provided that output values can be generated that meet the earlier-mentioned determined condition).

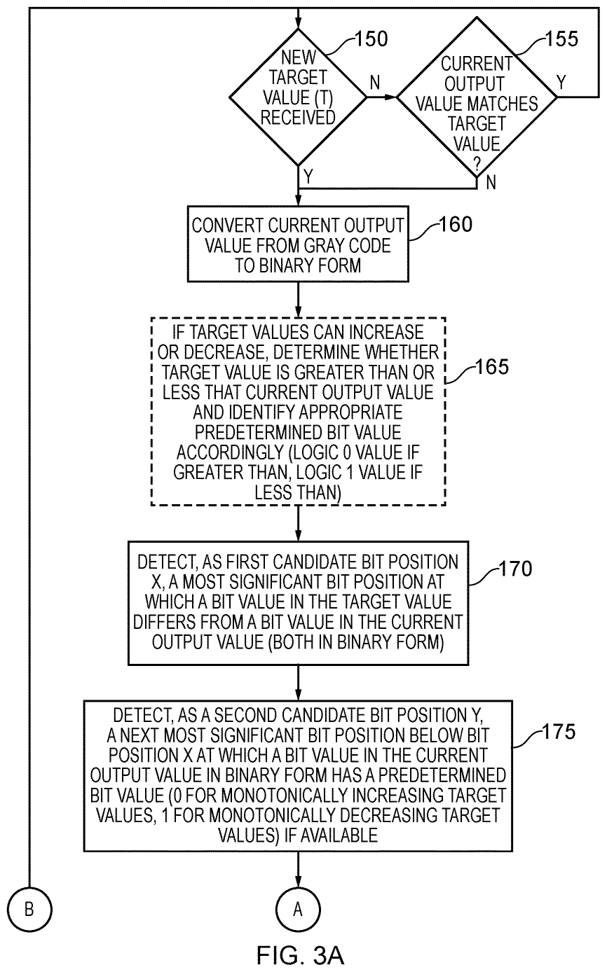

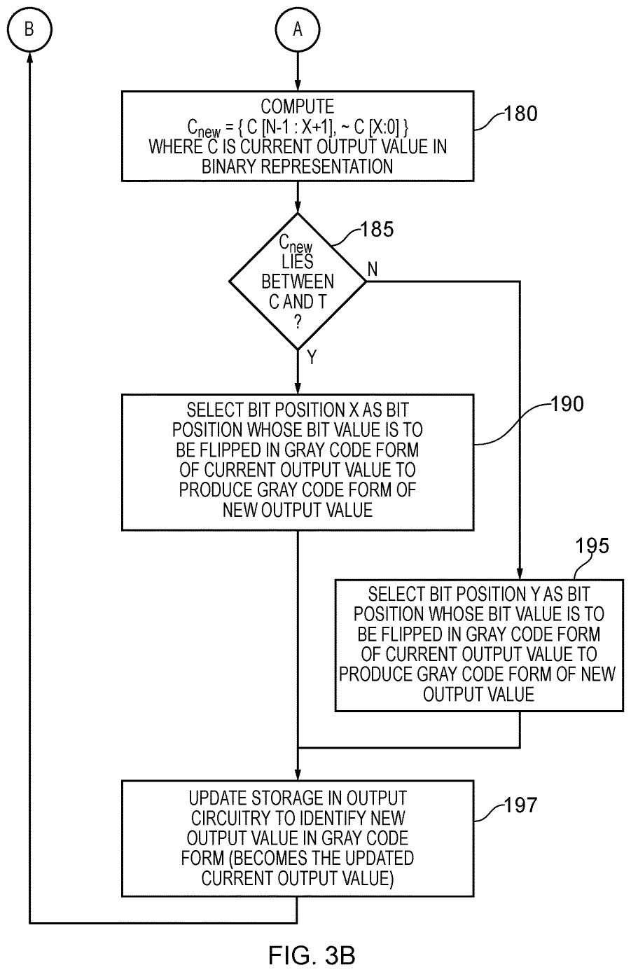

FIGS. 3A and 3B provide a flow diagram that illustrates in more detail the steps performed by the apparatus of FIG. 1 in accordance with a particular example implementation. Steps 150 and 155 correspond to steps 100 and 105 of FIG. 2, and hence when it is determined that a new target value has been received, or that the current output value does not match the currently provided target value, then the process proceeds to step 160 where the current output value is converted from Gray code representation to binary representation, for example using the Gray code to binary converter circuitry 50 of FIG. 1.

As mentioned earlier, if target values can either increase or decrease (as opposed to being constrained to either only monotonically increase, or only monotonically decrease), then at step 165 the direction determination circuitry 55 can be used to determine whether the target value is greater than or less than the current output value, and then cause the predetermined bit value identifier circuitry 60 to identify the appropriate predetermined bit value accordingly (a logic 0 value if the target value is greater than the current output value, and a logic 1 value if the target value is less than the current output value).

At step 170, the analysis circuitry 35 is arranged to detect, as a first candidate bit position X, a most significant bit position at which a bit value in the target value differs from a bit value in the current output value (both values being considered in binary form). Further, at step 175, the analysis circuitry 35 detects, as a second candidate bit position Y, a next most significant bit position below bit position X at which a bit value in the current output value in binary form has a predetermined bit value, if available (i.e. if there is at least one such bit position).

At step 180, the evaluation circuitry is arranged to compute a candidate new output value in binary representation (C_{new}) from the current output value in binary representation (C) as:

$${C}_{n e w} = \{ C [ N - 1 : X + 1 ] , ∼ C [ X ; 0 ] \}$$

such that bits X to 0 in C_{new} are the inverse of the corresponding bits X to 0 in C.

C_{new} hence represents the candidate new output value that would be formed were the bit value at the first candidate bit position X within the current output value in Gray code representation flipped in order to generate the new output value in Gray code representation.

At step 185, it is determined whether C_{new} lies between the values C and T, i.e. that selection of C_{new} as the new output value would cause the output value to transition towards the target value T but without overshooting the target value. If this is determined to be the case, then the process proceeds to step 190 where bit position X is selected as the bit position whose bit value is to be flipped in the Gray code representation of the current output value in order to produce the Gray code representation of the new output value. Conversely, if this is not the case, the process instead proceeds to step 195, where bit position Y is selected as the bit position whose bit value is to be flipped in the Gray code representation of the current output value in order to produce the Gray code representation of the new output value. Irrespective of which of steps 190 and 195 is performed, the process then proceeds to step 197, where the output circuitry 30 updates the storage 45 to identify the new output value in Gray code form (this new output value becoming the updated current output value at this point). The process then returns to step 150.

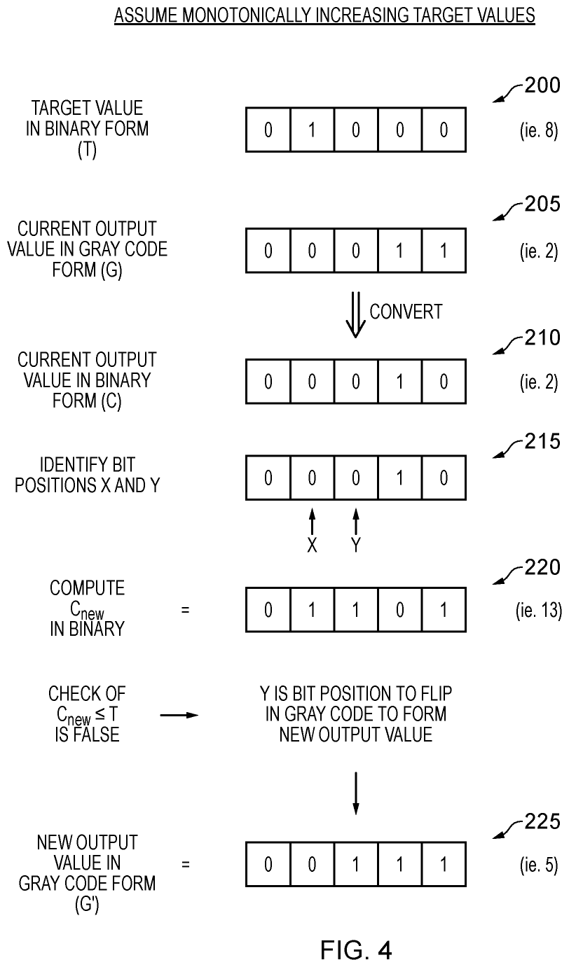

FIGS. 4 to 6 schematically illustrate particular examples of how a new output value may be generated from a current output value in dependence on a target value, in accordance with one example implementation. In FIG. 4, it is assumed that the target values received are monotonically increasing, that a received target value has the form 200, i.e. representing a value of 8, and that a current output value in Gray code representation has the form 205, i.e. representing a value of 2. The Gray code representation 205 is converted into the binary representation 210, and as indicated by the representation 215 the bit positions X and Y are determined by comparing the values C and T. In particular, for the example values shown, the most significant bit position at which the values of T and C differ is bit position 3 (assuming the bit positions are labelled bit positions 0 to 4 with bit position 0 being the least significant bit position), and the first bit position below bit position 3 that has a predetermined value of 0 in the current output value C is bit position 2.

The candidate new output value C_{new} is as shown by representation 220 (and as will be apparent from the earlier discussion is created by inverting all bits of the current output value C between the least significant bit position and bit position X (including bit position X)). This actually represents a value of 13, which is greater than the target value, hence causing the check as to whether C_{new} is less than or equal to the target value T to fail. As a result, it is bit position Y that is flipped in the Gray code form of the current output value in order to generate the Gray code form G′ of the new output value, shown in FIG. 4 by the representation 225, and representing the value 5. Hence, in this particular example it was not possible to perform the flip at bit position X, as this would have caused the new output value to overshoot the target value, and instead the flip was performed at bit position Y, causing the output value to be increased from 2 to 5 in a single update, thereby moving towards the desired target value 8.

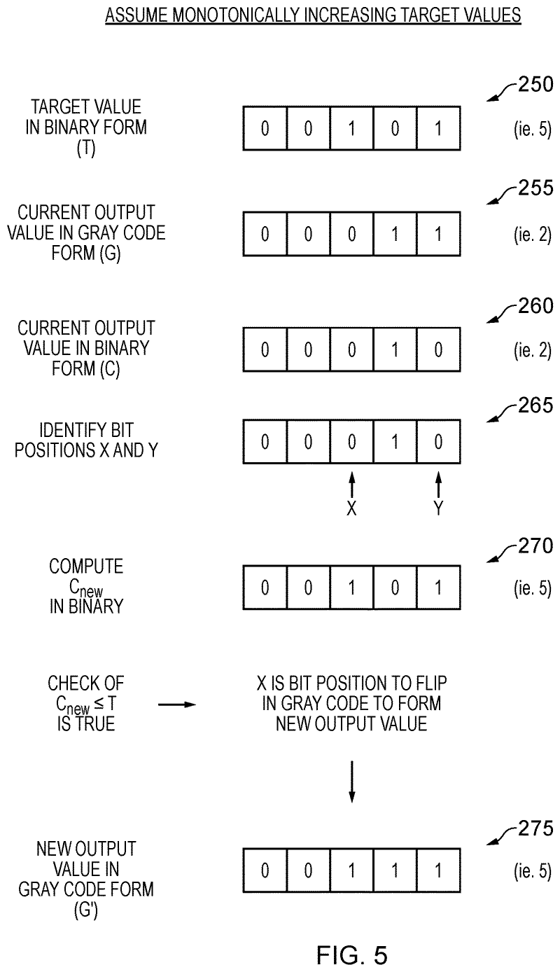

FIG. 5 illustrates a second example that also assumes that the target values are monotonically increasing, this example showing a case where the flip can be performed at bit position X. In particular, the target value has the representation 250, hence indicating a target value of 5, whilst the current output value in Gray code form has the representation 255, hence indicating a current output value of 2 (as also shown by the binary representation of the current output value 260).

The representation 265 indicates the identified bit positions X and Y based on the values of C and T, and the representation 270 indicates the determined candidate new output value C_{new}. This time the check as to whether C_{new} is less than or equal to T is passed (found to be true), and accordingly bit position X has its value flipped in the current output value in Gray code representation in order to produce the new output value in Gray code representation G′ (shown by representation 275 in FIG. 5, and representing the value 5). Hence in this particular example the current output value of 2 can be updated in one go to produce a new output value that matches the target value of 5, whilst still ensuring a Hamming distance of 1 between adjacent output values.

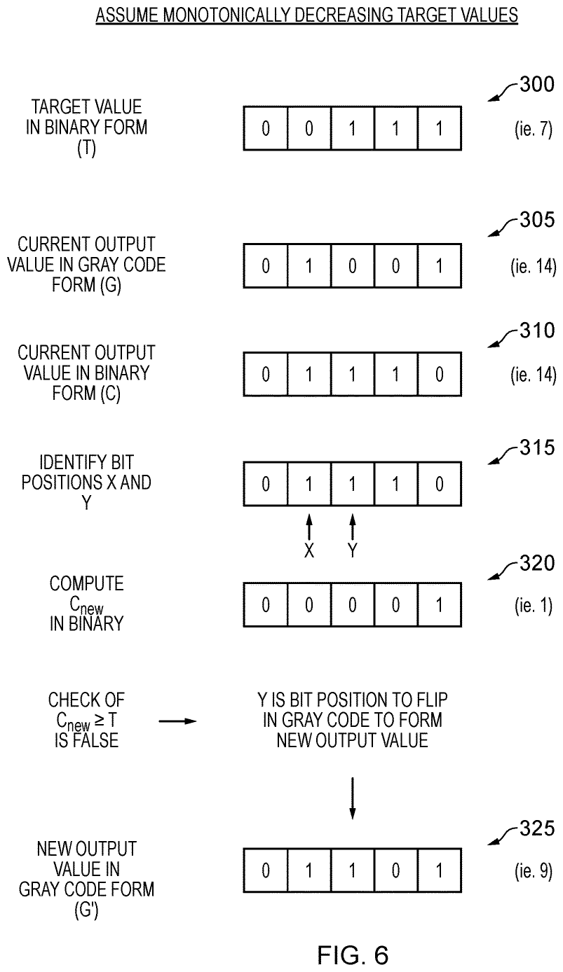

FIG. 6 illustrates a further example, where in this case it is assumed that the target values are monotonically decreasing, and hence the predetermined bit value that is considered when determining the bit position Y is a bit value of 1. As shown by the representation 300, it is assumed that the latest target value specifies a value of 7, whilst as indicated by the representation 305 the current output value in Gray code form represents a value of 14. The representation 310 shows the equivalent binary representation of the current output value C, and the representation 315 indicates the identified bit positions X and Y within the current output value C.

As shown by the representation 320, the candidate new output value C_{new} identifies a value of 1. Since the target values are assumed to be monotonically decreasing, the relevant check to perform is whether C_{new} is greater than or equal to the target value T, which in this case turns out to be false, and accordingly it is bit position Y that is flipped in the Gray code representation of the current output value in order to produce the new output value in Gray code representation, as indicated by the representation 325 shown in FIG. 6. In this particular example, it will be seen that the current output value 14 is changed to a new output value of 9, thereby moving the output value towards the target value of 7 whilst ensuring that a Hamming distance of 1 is observed between adjacent output values.

The above described technique exploits the fact that, whilst use of Gray code representation will always produce a Hamming distance of 1 between two output values that differ by the minimum adjustment amount (i.e. a value of 1), there may in some instances be larger adjustments in successive output values that will also result in those successive output values having a Hamming distance of 1 when in Gray code representation, and which may also meet the requirement of generating a new output value that lies between the current output value and the target value. By seeking to detect such situations, the described apparatus can accommodate arbitrary changes in a sequence of target values, whilst producing a corresponding sequence of output values that can accurately follow the sequence of target values by adjusting responsively to varying amounts of change in the target values, and whilst all the time ensuring that successive output values in the sequence in the Gray code representation have a Hamming distance of 1 with respect to each other.

The techniques described herein can be used in a variety of situations. However, in one particular example implementation it is assumed that the sequence of target values represent global time values within a data processing system. The above described apparatus can be included within a system to generate a sequence of Gray code values that seek to follow changes in the global time values. Since the target values represent global time values, it is expected that each subsequently received global time value will be larger than the preceding global time value, i.e. that the target values are monotonically increasing.

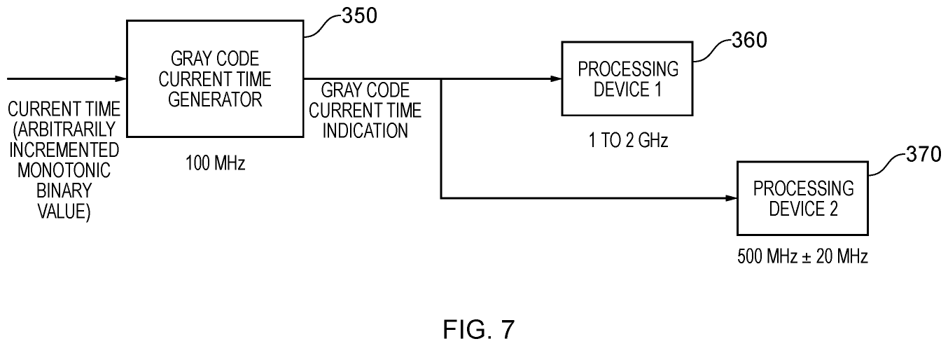

FIG. 7 shows such a system, where the Gray code current time generator circuitry 350 can be arranged to include the earlier-described apparatus shown for example in FIG. 1, and hence generates a sequence of Gray code current time indications that seeks to follow a sequence of current time indications received as target values. By using a Gray code representation this can ensure reliable detection of increases in the global time by a variety of different processing devices 360, 370 within the system, even when those processing devices may operate at different frequencies with respect to each other, and indeed may operate at a different frequency relative to the Gray code current time generator circuitry 350. In particular these different processing devices 360, 370 may operate asynchronously with regards to the Gray code current time generator 350, but will reliably detect changes in the time values due to the use of the Gray code representation that ensures that only a single bit will change its value between adjacent time indications output by the circuitry 350.

The amount by which successive instances of the current time value (as received at the input interface of the Gray code current time generator 350) change may vary over time, for example due to changes in the clock frequency at which the entity generating the global time value is operating, and/or changes in the clock frequency at which the Gray code current time generator circuitry 350 is sampling the global time value, and hence there may be arbitrary changes in the sampled global time values, where some changes are larger than other changes. Such a situation is likely to arise in data processing systems, for example as a result of switching clock frequency in response to requested performance and/or power levels. However, it will be apparent from the earlier discussion that when the techniques described herein are implemented within the Gray code current time generator 350, the Gray code current time generator 350 can accommodate such arbitrary changes in the received target values (i.e. the received indication of current time), enabling a sequence of Gray code current time indications to be output that meet the requirement of a Hamming distance of 1 between adjacent output values, whilst allowing the output values to seek to rapidly adjust to arbitrary changes in the received indication of current time.

The techniques described herein can be implemented within dedicated circuitry, with simple circuit components being used to perform the required computations, thereby enabling a low-area circuit to be produced, which in turn allows for a low cost and low power consumption solution to be developed. Alternatively the techniques described herein can be implemented by appropriate software executed on a general purpose data processing apparatus, if desired.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, System Verilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and System Verilog or other behavioural representations of the concepts that can be interpreted by a computer to enable simulation, functional and/or formal verification, and testing of the concepts. Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Concepts described herein may be embodied in a system comprising at least one packaged chip. The apparatus described earlier is implemented in the at least one packaged chip (either being implemented in one specific chip of the system, or distributed over more than one packaged chip). The at least one packaged chip is assembled on a board with at least one system component. A chip-containing product may comprise the system assembled on a further board with at least one other product component. The system or the chip-containing product may be assembled into a housing or onto a structural support (such as a frame or blade).

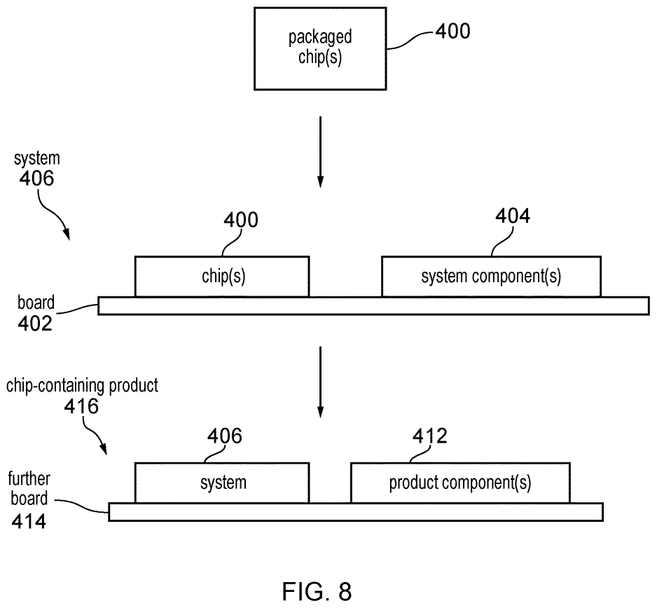

As shown in FIG. 8 one or more packaged chips 400, with the apparatus described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the apparatus described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e. small modular chips with particular functionality) may itself be referred to as a chip. A chiplet may be packaged individually in a semiconductor package and/or together with other chiplets into a multi-chiplet semiconductor package (e.g. using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g. plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g. a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

Although illustrative embodiments of the invention have been described in detail herein with reference to the accompanying drawings, it is to be understood that the invention is not limited to those precise embodiments, and that various changes, additions and modifications can be effected therein by one skilled in the art without departing from the scope and spirit of the invention as defined by the appended claims. For example, various combinations of the features of the dependent claims could be made with the features of the independent claims without departing from the scope of the present invention.

1. An apparatus comprising:
output circuitry arranged to output a sequence of output values in a given representation;
an input interface to receive a target value; and
modification circuitry to determine a new output value in the sequence from a current output value in the sequence in dependence on the target value, such that the new output value meets a determined condition, where the determined condition requires both that the new output value has a Hamming distance of 1 relative to the current output value when the new output value and the current output value are expressed in the given representation, and that the new output value lies between the current output value and the target value;
wherein the modification circuitry is arranged, when there are at least two possible new output values that meet the determined condition, to select as the new output value the possible new output value that is closest to the target value from amongst the at least two possible new output values.

2. An apparatus as claimed in claim 1, wherein the given representation is a Gray code representation.

3. An apparatus as claimed in claim 1, wherein:
the output circuitry has a storage to store the current output value in the given representation; and
the modification circuitry is arranged to output a modification value identifying which bit of the current output value in the given representation requires its bit value to be flipped in order to generate the new output value in the given representation; and
the output circuitry is arranged to use the modification value to update the storage to identify the new output value in the given representation.

4. An apparatus as claimed in claim 3, wherein at least each time a new instance of the target value is received at the input interface, the modification circuitry is arranged to determine the current output value from the output value in the given representation as currently stored in the storage, and to determine the new output value in the sequence from the determined current output value in dependence on the new instance of the target value.

5. An apparatus as claimed in claim 1, wherein:
the modification circuitry comprises analysis circuitry to perform an analysis operation using both the target value in binary representation and the current output value in binary representation in order to determine one or more candidate bit positions whose bit value within the current output value in the given representation could be flipped in order to generate the new output value in the given representation; and
the modification circuitry further comprises evaluation circuitry arranged, when at least two candidate bit positions are determined, to evaluate which one of the candidate bit positions, were its bit value within the current output value in the given representation flipped in order to generate the new output value in the given representation, would result in the new output value that is closest to the target value whilst also lying between the current output value and the target value.

6. An apparatus as claimed in claim 5, further comprising:
conversion circuitry to convert the current output value in the given representation into the current output value in binary representation, for provision to the modification circuitry.

7. An apparatus as claimed in claim 5, wherein:
the analysis circuitry is arranged to detect, as a first candidate bit position X, a most significant bit position at which a bit value in the target value in binary representation differs from a bit value in the current output value in binary representation.

8. An apparatus as claimed in claim 7, wherein the analysis circuitry is arranged to detect, as a second candidate bit position Y, a next most significant bit position below the first candidate bit position X at which a bit value in the current output value in binary representation is a predetermined bit value, provided there is at least one bit position below the first candidate bit position X at which a bit value in the current output value in binary representation has the predetermined bit value.

9. An apparatus as claimed in claim 8, wherein the evaluation circuitry is arranged to generate a candidate new output value that would be formed were the bit value at the first candidate bit position X within the current output value in the given representation flipped in order to generate the new output value in the given representation, and when the candidate new output value lies between the current output value and the target value, to identify the first candidate bit position X as the bit position whose bit value within the current output value in the given representation is to be flipped in order to generate the new output value in the given representation.

10. An apparatus as claimed in claim 9, wherein when the candidate new output value lies other than between the current output value and the target value, the evaluation circuitry is arranged to identify the second candidate bit position Y as the bit position whose bit value within the current output value in the given representation is to be flipped in order to generate the new output value in the given representation.

11. An apparatus as claimed in claim 9, wherein the given representation is a Gray code representation and the evaluation circuitry is arranged to compute the candidate new output value in binary representation (Cnew) from the current output value in binary representation (C) as:
$$Cnew = \{ C [ N - 1 : X + 1 ] , ∼ C [ X ; 0 ] \}$$
such that bits X to 0 in C_{new} are the inverse of the corresponding bits X to 0 in C.

12. An apparatus as claimed in claim 8, wherein the predetermined bit value is a logic 0 value when successive values of the target value as received at the input interface monotonically increase.

13. An apparatus as claimed in claim 8, wherein the predetermined bit value is a logic 1 value when successive values of the target value as received at the input interface monotonically decrease.

14. An apparatus as claimed in claim 8, wherein:
when any given target value as received at the input interface is allowed to increase or decrease relative to a preceding target value as received at the input interface, the modification circuitry comprises direction detection circuitry to determine whether a currently received target value is greater than or less than the current output value;
the predetermined bit value is a logic 0 value when the currently received target value is greater than the current output value; and
the predetermined bit value is a logic 1 value when the currently received target value is less than the current output value.

15. An apparatus as claimed in claim 1, wherein the target value represents a global time value.

16. A method of producing a new output value for inclusion within a sequence of output values that are output in a given representation, comprising:
receiving a target value;
employing modification circuitry to determine the new output value in the sequence from a current output value in the sequence in dependence on the target value, such that the new output value meets a determined condition, where the determined condition requires both that the new output value has a Hamming distance of 1 relative to the current output value when the new output value and the current output value are expressed in the given representation, and that the new output value lies between the current output value and the target value; and
when there are at least two possible new output values that meet the determined condition, selecting as the new output value the possible new output value that is closest to the target value from amongst the at least two possible new output values.

17. A non-transitory computer-readable medium to store computer-readable code for fabrication of an apparatus comprising:
output circuitry arranged to output a sequence of output values in a given representation;
an input interface to receive a target value; and
modification circuitry to determine a new output value in the sequence from a current output value in the sequence in dependence on the target value, such that the new output value meets a determined condition, where the determined condition requires both that the new output value has a Hamming distance of 1 relative to the current output value when the new output value and the current output value are expressed in the given representation, and that the new output value lies between the current output value and the target value;
wherein the modification circuitry is arranged, when there are at least two possible new output values that meet the determined condition, to select as the new output value the possible new output value that is closest to the target value from amongst the at least two possible new output values.

18. A system comprising:
the apparatus of claim 1, implemented in at least one packaged chip;
at least one system component; and
a board,
wherein the at least one packaged chip and the at least one system component are assembled on the board.

19. A chip-containing product comprising the system of claim 18 assembled on a further board with at least one other product component.
